(19) United States
(12) Patent Application Publication
(10) Pub. No.: US 2026/0033170 A1
(43) Pub. Date: Jan. 29, 2026

(54) DISPLAY PANEL AND DISPLAY DEVICE

(71) Applicants: Chongqing BOE Display Technology Co., Ltd., Chongqing (CN); BOE Technology Group Co., Ltd., Beijing (CN)

(72) Inventors: Tianlong ZHAO, Beijing (CN); Wentao WANG, Beijing (CN); Faming JIANG, Beijing (CN); Teng CHEN, Beijing (CN); Liang ZHOU, Beijing (CN); Weixing GONG, Beijing (CN); Lingling WANG, Beijing (CN); Dawei SHI, Beijing (CN)

(73) Assignees: Chongqing BOE Display Technology Co., Ltd., Chongqing (CN); BOE Technology Group Co., Ltd., Beijing (CN)

(21) Appl. No.: 19/102,857

(22) PCT Filed: Aug. 14, 2024
(86) PCT No.: PCT/CN2024/112082

§ 371 Date: Feb. 11, 2025

(30) Foreign Application Priority Data
Sep. 27, 2023 (CN) 202311266462.3

(51) Int. Cl. H10K 59/126; H10K 59/131

(52) U.S. Cl. CPC H10K 59/126; H10K 59/131

(57) ABSTRACT

Disclosed is a display panel, including a light shielding layer and at least two pixel circuits. Each pixel circuit includes at least two types of transistors for receiving different signals. The light shielding layer includes a first light shielding structure and a second light shielding structure. Orthographic projections of the first and second light shielding structures on the driving circuit layer overlap with the active portions of different types of transistors, adjacent first light shielding structures are connected together, and/or adjacent second light shielding structures are connected together, which may increase the static discharge area and path of the light shielding layer, so that static electricity accumulated in the process may be released in a timely manner or evenly distributed, to prevent static electricity from damaging the shading layer or other film layers, and achieve a good display effect. Also disclosed is a display device including the display panel.

### CROSS-REFERENCE TO RELATED APPLICATIONS

This application is a National Stage application of PCT/CN2024/112082, filed on Aug. 14, 2024, which claims priority to Chinese Patent Application Number 202311266462.3, titled “Display Panel and Display Device” and filed on Sep. 27, 2023. The entire contents of each application are incorporated herein by reference in their entirety.

### TECHNICAL FIELD

The present disclosure relates to the field of display technology, specifically to a display panel and a display device.

### BACKGROUND

Some display panels are equipped with a light shielding layer to block thin film transistors in pixel circuits.

### SUMMARY

The present disclosure provides a display panel and a display device.

According to one aspect of the present disclosure, a display panel includes a base substrate, a driving circuit layer and a light shielding layer. The driving circuit layer is provided on a side of the base substrate, and the driving circuit layer includes at least two pixel circuits arranged along a row direction and arranged along a column direction, the column direction being perpendicular to the row direction, and each pixel circuit including at least two types of transistors for receiving different signals. The light shielding layer provided between the driving circuit layer and the base substrate, the light shielding layer including at least two light shielding structure groups, each light shielding structure group including a first light shielding structure and a second light shielding structure, the first light shielding structure inputting a first signal, the second light shielding structure inputting a second signal, the first light shielding structure and the second light shielding structure extending along the row direction, and at least two first light shielding structures and at least two second light shielding structures arranged along the column direction. One of the light shielding structure groups blocks one of the pixel circuits; an orthographic projection of the first light shielding structure on the driving circuit layer and an orthographic projection of the second light shielding structure on the driving circuit layer separately overlap with active portions of different types of transistors; and two adjacent first light shielding structures are connected together and/or two adjacent second light shielding structures are connected together.

In an embodiment of the present disclosure, each pixel circuit includes a first reset transistor, a compensation transistor, a driving transistor, a writing transistor, a first light-emitting control transistor, a second light-emitting control transistor, a second reset transistor, and a storage capacitor; a first pole of the first reset transistor is configured to receive a first reset signal, and a second pole of the first reset transistor is connected to a gate of the driving transistor and a first pole plate of the storage capacitor; a first pole of the compensation transistor is connected to a second pole of the driving transistor, and a second pole of the compensation transistor is connected to the gate of the driving transistor; the compensation transistor has two channels connected in series; a first pole of the writing transistor is connected to a data line, and a second pole of the writing transistor is connected to a first pole of the driving transistor; a first pole of the first light-emitting control transistor and a second pole plate of the storage capacitor are connected by a power line, and a second pole of the first light-emitting control transistor is connected to the first pole of the driving transistor; a first pole of the second light-emitting control transistor is connected to the second pole of the driving transistor, and a second pole of the second light-emitting control transistor is connected to a first electrode of a light-emitting device; a first pole of the second reset transistor is configured to receive a second reset signal, and a second pole of the second reset transistor is connected to the second pole of the second light-emitting control transistor; the orthographic projection of the first light shielding structure on the driving circuit layer overlaps with an active portion of the first reset transistor, an active portion of a threshold compensation transistor, an active portion of the writing transistor, and an active portion of the second reset transistor of the pixel circuit in a previous row; the orthographic projection of the second light shielding structure on the driving circuit layer overlaps with an active portion of the driving transistor.

In an embodiment of the present disclosure, the first light shielding structure includes a first light shielding portion and a second light shielding portion; the first light shielding portion and the second light shielding portion extend along the row direction and are arranged along the column direction; an orthographic projection of the first light shielding portion on the driving circuit layer overlaps with an active portion of the compensation transistor and the active portion of the writing transistor; and an orthographic projection of the second light shielding portion on the driving circuit layer overlaps with the active portion of the first reset transistor and the active portion of the second reset transistor of the pixel circuit in the previous row.

In an embodiment of the present disclosure, first light shielding portions and second light shielding portions of at least two first light shielding structures are arranged alternately along the column direction, and the second light shielding structure is provided between the first light shielding portion and the second light shielding portion of a same first light shielding structure, or between the first light shielding portion and the second light shielding portion of adjacent first light shielding structures.

In an embodiment of the present disclosure, two adjacent first light shielding structures are connected together, and two adjacent second light shielding structures are connected together.

In an embodiment of the present disclosure, the first light shielding portion and the second light shielding portion of the same first light shielding structure are connected by at least three first traces extending along the column direction, the first light shielding portion on one side of the light shielding layer along the column direction is continuous and uninterrupted, the remaining first light shielding portion and all the second light shielding portions are provided with at least two interruptions along the row direction, and there is one interruption between every two adjacent first traces; the second light shielding structure is provided between the first light shielding portion and the second light shielding portion of the same first light shielding structure, the second light shielding structure on another side of the light shielding layer along the column direction is continuous and uninterrupted, the remaining second light shielding structure is partitioned into a second light shielding sub-structure between every two of the first traces, two adjacent second light shielding sub-structures along the column direction are connected by a second trace, and the second trace is within the interruption; the first light shielding portion and the second light shielding portion of different first light shielding structures are connected by a third trace extending along the column direction, the third trace is between the first trace and the second trace.

In an embodiment of the present disclosure, the first light shielding portion and the second light shielding portion of the same first light shielding structure are connected by a first trace extending along the column direction; the second light shielding structure is provided between the first light shielding portion and the second light shielding portion of the same first light shielding structure; the second light shielding structure is connected by a second trace extending along the column direction; the first trace is on one side of the light shielding layer along the row direction; the second trace is on another side of the light shielding layer along the row direction; the first light shielding portion and the second light shielding portion of different first light shielding structures are connected by a third trace extending along the column direction.

In an embodiment of the present disclosure, the third trace and the second trace are on a same straight line.

In an embodiment of the present disclosure, one end of the first light shielding portion and one end of the second light shielding portion of the same first light shielding structure are connected by a first trace extending along the column direction; the second light shielding structure is provided between the first light shielding portion and the second light shielding portion of adjacent first light shielding structures; different second light shielding structures are connected end-to-end by a second trace, and the second trace is provided along the row direction at one end of the first light shielding structure away from the first trace; first traces of adjacent first light shielding structures are respectively on different sides of the light shielding layer along the row direction; and one third trace is provided on an outer side of each of the two first traces, and the third trace is connected to the first trace adjacent thereto.

In an embodiment of the present disclosure, the first light shielding portion includes a plurality of first light shielding units and a plurality of second light shielding units connected by a first connection line; the first light shielding units and the second light shielding units are alternately arranged along the row direction; at least one first light shielding unit and at least one second light shielding unit are provided between every two adjacent second traces; an orthographic projection of each first light shielding unit on the driving circuit layer overlaps with the active portion of the compensation transistor; and an orthographic projection of the second light shielding unit on the driving circuit layer overlaps with the active portion of the writing transistor.

In an embodiment of the present disclosure, the active portion of the compensation transistor includes a first channel region and a second channel region, the first light shielding unit includes a first light shielding block and a second light shielding block connected to each other, the first light shielding block extends along the row direction, the second light shielding block extends along the column direction, an orthographic projection of the first light shielding block on the driving circuit layer overlaps with the first channel region, and an orthographic projection of the second light shielding block on the driving circuit layer overlaps with the second channel region.

In an embodiment of the present disclosure, the second light shielding portion includes a plurality of third light shielding units connected to each other, and an orthographic projection of each third light shielding unit on the driving circuit layer overlaps with the active portion of the first reset transistor and the active portion of the second reset transistor of the pixel circuit in the previous row.

According to another aspect of the present disclosure, a display device including the display panel provided by any one of embodiments of the above aspect of the present disclosure.

The display panel of the present disclosure includes the light shielding layer and at least two pixel circuits. The light shielding layer includes at least two light shielding structure groups, with one light shielding structure group shielding one pixel circuit. Each light shielding structure group includes the first light shielding structure for inputting the first signal and the second light shielding structure for inputting the second signal. The pixel circuit includes at least two types of transistors for receiving different signals. The orthographic projections of the first light shielding structure and the second light shielding structure on the driving circuit layer overlap with active portions of different types of transistors. Adjacent first light shielding structures are connected together and/or adjacent second light shielding structures are connected together.

It should be understood that the above general description and the subsequent detailed description are only exemplary and explanatory and are not restrictive of the present disclosure.

### BRIEF DESCRIPTION OF THE DRAWINGS

The accompanying drawings, which are incorporated into the specification and form a part of the specification, illustrate embodiments in accordance with the present disclosure and are used together with the specification to explain the principles of the present disclosure. Apparently, the drawings described below are only some embodiments of the present disclosure, and other drawings may be obtained by those skilled in the art based on these drawings without creative effort.

FIG. 1 is a schematic plan view of a light shielding layer according to an embodiment of the present disclosure when adjacent light shielding structure groups are independent of each other.

FIG. 2 is a schematic sectional view of a display panel according to an embodiment of the present disclosure.

FIG. 3 is a schematic diagram of a pixel circuit according to an embodiment of the present disclosure.

FIG. 4 is a schematic plan view of a light shielding layer according to an embodiment of the present disclosure when the light shielding layer includes a first light shielding section, a second light shielding section, and a third light shielding section.

FIG. 5 is a schematic plan view of a light shielding layer according to an embodiment of the present disclosure when a first trace and a second trace are on different sides of the light shielding layer along a row direction.

FIG. 6 is a schematic plan view of a light shielding layer according to an embodiment of the present disclosure when a first pin is provided on a third trace.

FIG. 7 is a schematic plan view of a light shielding layer according to an embodiment of the present disclosure when two adjacent first light shielding structures are connected together and two adjacent second light shielding structures are independent of each other.

FIG. 8 is a schematic plan view of a light shielding layer according to an embodiment of the present disclosure when two adjacent second light shielding structures are connected together and two adjacent first light shielding structures are independent of each other.

### DETAILED DESCRIPTION

Exemplary embodiments will be now described more fully with reference to the accompanying drawings. However, the exemplary embodiments may be embodied in a variety of forms and should not be construed as limiting the embodiments set forth herein. Instead, these embodiments are provided so that the present disclosure will be thorough and complete, and the concepts of the exemplary embodiments will be fully given to those skilled in the art. Same reference numbers denote the same or similar structures in the figures, and thus the detailed description thereof will be omitted. In addition, the drawings are merely schematic illustrations of the present disclosure, and are not necessarily drawn to scale.

Although relative terms such as “above” and “below” are used in the specification to describe the relative relationship between one component and another component marked in the drawings, these terms are used herein only for the sake of convenience, for example, according to exemplary directions described in the drawings. It may be understood that if a device marked in the drawings is flipped upside down, a component described as “above” will become a component described as “below”. When a structure is “above” another structure, it may mean that the structure is integrally formed on another structure, or the structure is “directly” disposed on another structure, or the structure is “indirectly” disposed on another structure through an additional structure.

Words such as “one”, “a/an”, “the”, “said” and “at least one” are used to indicate the existence of one or more elements/components/and others. Terms such as “including” and “having” are used to indicate open-ended inclusion and mean that there may be additional elements/component parts/and others in addition to the listed elements/component parts/and others. Terms such as “first”, “second” and “third” are only used as markers and do not limit the number of objects modified after them.

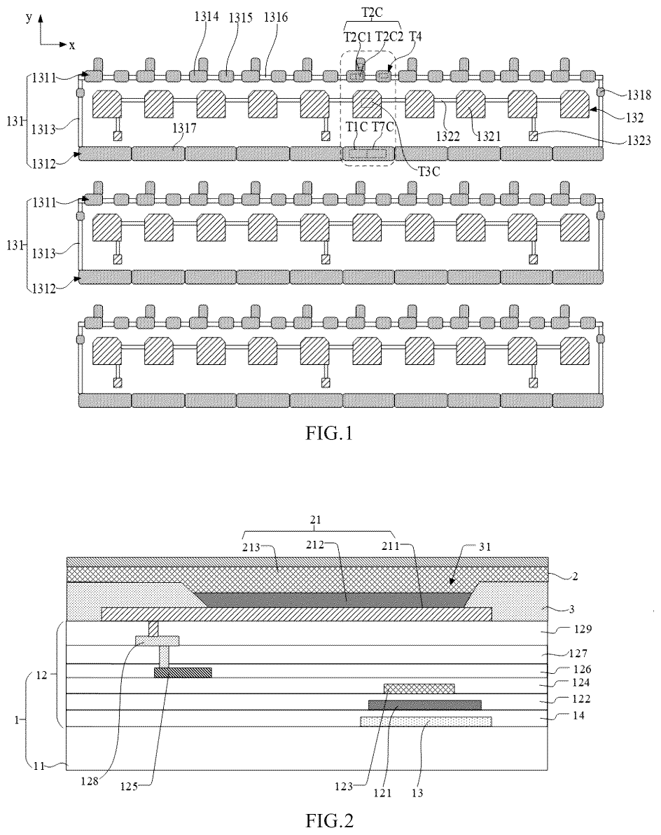

As shown in FIG. 1, in order to prevent light irradiating on transistors from affecting electrical characteristics of the transistors, a light shielding layer 13 is gradually introduced into a manufacturing process of a driving backplane 1 of an OLED display panel. Taking a 7T1C pixel circuit used in driving backplane 1 as an example, a commonly used light shielding method is to use the light shielding layer 13 to shield a first reset transistor T1, a compensation transistor T2, a driving transistor T3, a writing transistor T4, and a second reset transistor T7. The light shielding layer 13 may include a first light shielding structure 131 and a second light shielding structure 132. The first light shielding structure 131 shields the driving transistor T3, and the second light shielding structure 132 shields the first reset transistor T1, the compensation transistor T2, the writing transistor T4, and the second reset transistor T7. To prevent poor uniformity of transistor characteristics caused by floating of the light shielding layer 13, a voltage signal needs to be applied to the light shielding layer 13. A first signal may be applied to the first light shielding structure 131, and a second signal may be applied to the second light shielding structure 132. It should be noted that the first signal herein may be a constant voltage signal VDD, and the second signal may be a Gate signal.

The first light shielding structure 131 and the second light shielding structure 132 form a light shielding structure group. In order to avoid short circuits between the first light shielding structure 131 and the second light shielding structure 132, which may cause signal abnormalities, the prior light shielding layer 13 is set as a single pixel circuit using a set of light shielding structure groups. Each light shielding structure group exists independently, and the static electricity accumulated by a single light shielding structure group during the process is not easily released in a timely manner. With the gradual increase in handling, cleaning, and processes during the production of display panels, when static electricity accumulates to a certain amount and cannot be released, it may easily cause electrostatic damage to the light shielding layer 13 or other film layers, resulting in poor display performance.

Accordingly, the present disclosure provides a display panel. As shown in FIGS. 2 to 8, the display panel includes a base substrate 11, a driving circuit layer 12, and the light shielding layer 13. The driving circuit layer 12 is provided on one side of the base substrate 11, the driving circuit layer 12 includes at least two pixel circuits arranged along the row direction and the column direction, with the column direction perpendicular to the row direction. The pixel circuit includes at least two types of transistors for receiving different signals; the light shielding layer 13 is provided between the driving circuit layer 12 and the base substrate 11. The light shielding layer 13 includes at least two light shielding structure groups, each of which includes the first light shielding structure 131 and the second light shielding structure 132. The first light shielding structure 131 is input the first signal, and the second light shielding structure 132 is input the second signal. The first light shielding structure 131 and the second light shielding structure 132 extend along the row direction, and at least two first light shielding structures 131 and at least two second light shielding structures 132 are arranged along the column direction; one light shielding structure group blocks one pixel circuit, and the orthographic projections of the first light shielding structure 131 and the second light shielding structure 132 on the driving circuit layer 12 overlap with the active portions of different types of transistors. Adjacent first light shielding structures 131 are connected together, and/or adjacent second light shielding structures 132 are connected together.

Each light shielding structure group includes the first light shielding structure 131 input with the first signal and the second light shielding structure 132 input with the second signal. Adjacent first light shielding structures 131 are connected together, and/or adjacent second light shielding structures 132 are connected together, which may increase the electrostatic discharge area and path of the light shielding layer 13, so that the accumulated static electricity during the process may be timely released or evenly distributed, preventing static electricity from damaging the light shielding layer 13 or other film layers, and achieving good display effect.

The following provides a detailed explanation of the display panel involved in the embodiments of the present disclosure, based on specific examples.

As shown in FIG. 2, the display panel includes the driving backplane 1 and a light-emitting layer 2. The driving backplane 1 includes the base substrate 11 and the driving circuit layer 12. The driving circuit layer 12 is provided on one side of the base substrate 11, and the light-emitting layer 2 is provided on the side of the driving circuit layer 12 away from the base substrate 11. The base substrate 11 may carry circuit layers, the base substrate 11 may be a hard or flexible structure, which may be a single-layer or multi-layer structure, but will not be specifically limited herein. The driving circuit layer 12 is used to drive the light-emitting devices 21 to independently emit light and display images. The driving circuit may include the pixel circuit, which is connected to the light-emitting device 21.

The base substrate 11 may be an inorganic material base substrate 11 or an organic material base substrate 11. For example, in one embodiment of the present disclosure, the material of the base substrate 11 may be glass materials such as soda-lime glass, quartz glass, sapphire glass, or metal materials such as stainless steel, aluminum, nickel, etc.

In another embodiment of the present disclosure, the material of the base substrate 11 may be polymethyl methacrylate (PMMA), polyvinyl alcohol (PVA), polyvinyl enol (PVP), polyether sulfone (PES), polyimide, polyamide, polyacetal, poly carbonate (PC), polyethylene terephthalate (PET), polyethylene nathalate (PEN), or a combination thereof.

In another embodiment of the present disclosure, the base substrate 11 may also be a flexible base substrate 11, for example, the material of the base substrate 11 may be polyimide (PI). The base substrate 11 may further be a composite of a plurality of layers of materials. For example, in one embodiment of the present disclosure, the base substrate 11 may include a bottom film layer, a pressure-sensitive adhesive layer, a first polyimide layer, and a second polyimide layer stacked in sequence.

The driving circuit layer 12 includes a plurality of pixel circuits, the light-emitting layer 2 includes a plurality of light-emitting devices 21. The number of pixel circuits may be multiple, and the array distribution may be in a plurality of rows and columns. One pixel circuit may be connected to one light-emitting device 21. Of course, there may also be cases where one pixel circuit is connected to a plurality of light-emitting devices 21. Only the one-to-one correspondence between pixel circuits and light emitting devices 21 is taken as an example for explanation herein.

Each pixel circuit may include a plurality of transistors and storage capacitors, and the channel regions of each transistor may be arranged in the same layer, all of which are made of semiconductor materials such as polycrystalline silicon. The pixel circuit may include a plurality of transistors and the pixel circuit may further include capacitors, which may be 2T1C, 3T1C, 7T1C, and other pixel circuits. Taking 7T1C as an example, 7T1C represents a pixel circuit consisting of 7 transistors and 1 capacitor.

The transistors in the pixel circuit of the present disclosure may be N-type transistors, P-type transistors, or both. The transistor may have a gate, a first pole, and a second pole. The gate may control the on and off of the transistor, and the first and second poles may be used for input and output signals. The first pole may be the source of the transistor, and the second pole may be the drain of the transistor. But when the working state of the transistor changes, such as the direction of current changes, the source and drain of the transistor may be interchanged.

The driving circuit layer 12 includes a semiconductor layer 121, a gate insulation layer 122, a gate layer 123, a dielectric layer 124, a first source-drain layer 125, a passivation layer 126, a first planarization layer 127, a second source-drain layer 128, and a second planarization layer 129 arranged in sequence along the direction away from the base substrate 11. The materials of the first planarization layer 127 and the second planarization layer 129 may be transparent organic materials such as resin, and the surface of the planarization layer is flat away from the driving backplate 1, so as to provide the light-emitting device 21 on it.

As shown in FIG. 2, the side of the driving circuit layer 12 away from the base substrate 11 is provided with a pixel define layer 3, and a pixel opening 31 is provided on the pixel define layer 3. Each light-emitting device 21 may be arranged in an array within the pixel opening 31. The light-emitting device 21 may be an organic light emitting diode, which includes a first electrode 211, a light emitting material layer 212, and a second electrode 213 stacked in a direction away from the base substrate 11, wherein, a first electrodes 211 is connected to a pixel circuit, and the first electrode 211 serves as an anode, which may be a single-layer or multi-layer structure, its material may include one or more of conductive metals, metal oxides, and alloys. The first electrode 211 may be a light shielding structure, for example, the first electrode 211 may include three layers of metal, with the material of the middle layer of metal being silver, aluminum, etc., and the material of the other two layers of metal being titanium or other metals, which are not specifically limited herein.

As shown in FIG. 2, the light-emitting material layer 212 is at least partially provided within the pixel opening 31, and may include a hole injection layer, a hole transport layer, the light-emitting material layer 212, an electron transport layer, and an electron injection layer stacked in sequence along the direction away from the base substrate 11. By recombination of holes and electrons in the light-emitting material layer 212 into excitons, visible light may be generated by emitting photons from the excitons. The specific luminescent principle will not be described in detail herein. The light-emitting material layer 212 may be distributed in an array, and each light-emitting device 21 has an independent light-emitting material layer 212, so that each light-emitting device 21 may emit light independently, and the luminescent color of different light-emitting devices 21 may be different. For example, the number of light-emitting material layers 212 is multiple, and the array is distributed in each pixel opening 31, and stacked with the first electrode 211 exposed from the pixel opening 31. Alternatively, each light-emitting material layer 212 may share at least a portion of the film layer except for the light-emitting material layer 212, but the light-emitting material layers 212 may be independently arranged, resulting in light-emitting devices 21 with different luminescent colors.

As shown in FIG. 2, the second electrode 213 may cover the light-emitting material layer 212, which may serve as the cathode of the light-emitting device 21. The second electrode 213 may be a single-layer or multi-layer structure, and its material may include one or more of conductive metals, metal oxides, and alloys. Each light-emitting device 21 may share the same second electrode 213. Specifically, the second electrode 213 is a continuous conductive layer covering the light-emitting material layer 212 of each light-emitting device 21 and the pixel define layer 3. That is to say, the orthographic projection of the second electrode 213 on the pixel define layer 3 covers each pixel opening 31.

As shown in FIG. 2, in order to limit the range of each light-emitting device 21, the pixel define layer 3 may be arranged on the surface of the planarization layer facing away from the base substrate 11. The pixel define layer 3 may be used to separate each light-emitting device 21, thereby preventing adjacent light-emitting devices 21 from crossing colors. Specifically, the pixel define layer 3 may have a plurality of pixel openings 31, each of which exposes a corresponding first electrode 211 one by one, and the boundary of the pixel opening 31 is within the boundary of the exposed first electrode 211. The range defined by each pixel opening 31 is the range of a light-emitting device 21.

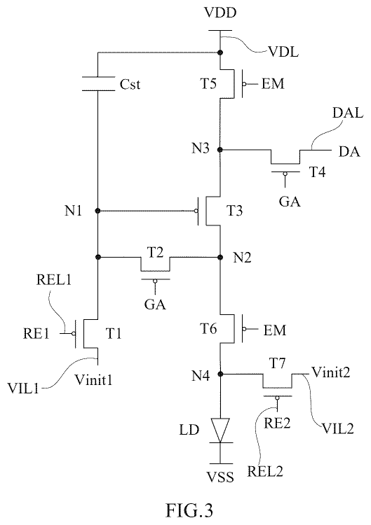

As shown in FIG. 3, the pixel circuit may be a 7T1C structure, which may have 7 transistors and 1 capacitor, namely a first reset transistor T1, a compensation transistor T2, a driving transistor T3, a writing transistor T4, a first light-emitting control transistor T5, a second light-emitting control transistor T6, a second reset transistor T7, and a storage capacitor Cst.

As shown in FIG. 3, the first pole of the first reset transistor T1 is connected to the first reset signal line VIL1 for receiving the first reset signal Vinit1, and the second pole is connected to the gate of the driving transistor T3 and the first pole plate of the storage capacitor Cst.

The first pole of the compensation transistor T2 is connected to the second pole of the driving transistor T3, and the second pole is connected to the gate of the driving transistor T3.

The first pole of the writing transistor T4 is connected to the data line DAL for receiving data signal DA, and the second pole is connected to the first pole of the driving transistor T3.

The first pole of the first light-emitting control transistor T5 and the second pole plate of the storage capacitor Cst are connected to the power line VDL for receiving the first power signal VDD, and the second pole is connected to the first pole of the driving transistor T3.

The first pole of the second light-emitting control transistor T6 is connected to the second pole of the driving transistor T3, and the second pole is connected to the first electrode 211 of a light-emitting device 21.

The first pole of the second reset transistor T7 is connected to the second reset signal line VIL2 for receiving the second reset signal Vinit2, and the second pole is connected to the second pole of the second light-emitting control transistor T6. The second electrode 213 of the light-emitting device 21 may receive the second power signal VSS.

Meanwhile, in order to control the conduction and turn off of each transistor, the gate of the first reset transistor T1 is connected to the first reset control line REL1 for inputting the first reset control signal RE1, and the gate of the second reset transistor T7 is connected to the second reset control line REL2 for inputting the second reset control signal RE2. The gates of the compensation transistor T2 and the writing transistor T4 are connected to the scanning line GL for inputting the scanning signal GA. The gates of the first light-emitting control transistor T5 and the second light-emitting control transistor T6 are connected to the light-emitting control line EML for inputting the light-emitting control signal EM. The pixel circuit may be used to drive the connected light-emitting device 21 to emit light in response to signals provided by the connected signal terminals.

The gate layer 123 may include the first pole plate Cst1 of the storage capacitor Cst, the scanning line GL, the first reset control line REL1, the second reset control line REL2, and the light-emitting control line EML, and the region where the scanning line GL overlaps with the semiconductor layer 121S is the gates of the writing transistor T4 and the compensation transistor T2. The region where the first reset control line REL1 overlaps with the semiconductor layer 121S is the gate of the first reset transistor T1. The area where the second reset control line REL2 overlaps with the semiconductor layer 121S is the gate of the second reset transistor T7. The area where the light-emitting control line EML overlaps with the semiconductor layer 121S is the gates of the first light-emitting control transistor T5 and the second light-emitting control transistor T6. The area where the first pole plate Cst1 overlaps with the semiconductor layer 121S is the gate of the driving transistor T3, that is, the first pole plate Cst1 is reused as the gate of the driving transistor T3. Wherein, the scanning line GL and the semiconductor layer 121S have interconnected first and second channel regions T1C1 and T1C2, the first channel region T1C1 and the second channel region T1C2 are the channels of the compensation transistor T2.

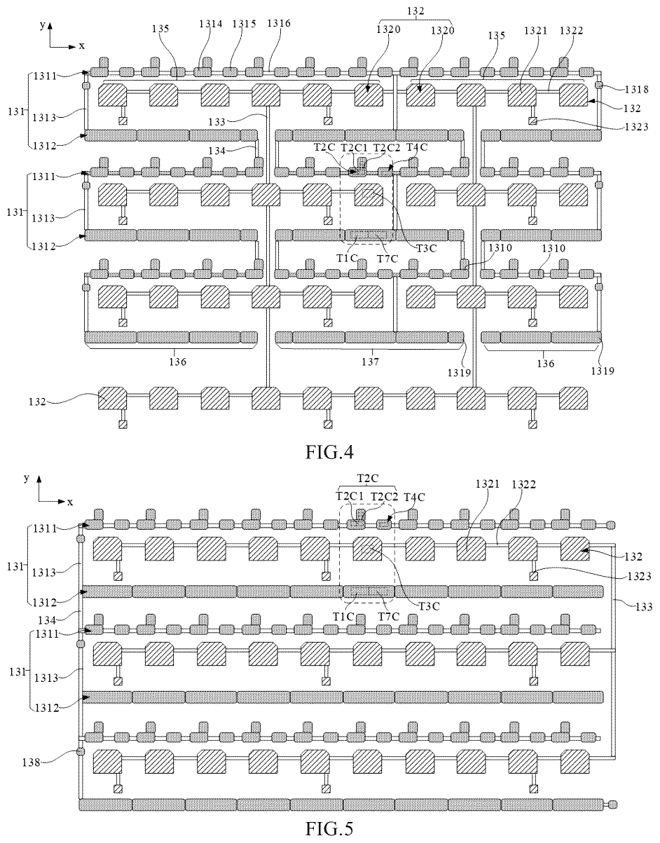

As shown in FIG. 4, the display panel further includes the light shielding layer 13, the light shielding layer 13 is between the driving circuit layer 12 and the base substrate 11. A buffer layer 14 may be provided between the light shielding layer and the driving circuit layer. The light shielding layer 13 includes a plurality of light shielding structure groups arranged along the column direction, each light shielding structure group including the first light shielding structure 131 and the second light shielding structure 132. The first light shielding structure 131 is input the first signal, and the second light shielding structure 132 is input the second signal. The first light shielding structure 131 and the second light shielding structure 132 extend along the row direction, and at least two first light shielding structures 131 and at least two second light shielding structures 132 are arranged along the column direction.

Each pixel circuit is arranged along the row direction, and a plurality of pixel circuits are arranged along the column direction. One light shielding structure group shields one pixel circuit. The orthographic projection of the first light shielding structure 131 on the driving circuit layer 12 covers the active portion of the driving transistor T3, and the orthographic projection of the second light shielding structure 132 on the driving circuit layer 12 covers the active portion T1C of the first reset transistor T1, the active portion T2C of the threshold compensation transistor T2, the active portion T4C of the writing transistor T4, and the active portion T7C of the second reset transistor T7 of the pixel circuit in the previous row.

The first light shielding structure 131 includes a first light shielding portion 1311, the first light shielding portion 1311 and the second light shielding portion 1312 extend along the row direction and are arranged along the column direction. The first light shielding portion 1311 includes a plurality of first light shielding units 1314 and a plurality of second light shielding units 1315 connected by a first connection line 1316. The first light shielding units 1314 and the second light shielding units 1315 are alternately arranged along the row direction, and at least one first light shielding unit 1314 and at least one second light shielding unit 1315 are provided between every two adjacent second traces 133. The orthographic projection of the first light shielding unit 1314 on the driving circuit layer 12 covers the active portion T2C of the compensation transistor T2, and the orthographic projection of the second light shielding unit 1315 on the driving circuit layer 12 covers the active portion T4C of the writing transistor T4.

The active portion T2C of the compensation transistor T2 mentioned above may include the first channel region T2C1 and the second channel region T2C2. Therefore, the first light shielding unit 1314 may include interconnected first and second light shielding blocks, with the first light shielding block extending in the row direction and the second light shielding block extending in the column direction. The orthographic projection of the first light shielding block on the driving circuit layer 12 covers the first channel region, and the orthographic projection of the second light shielding block on the driving circuit layer 12 covers the second channel region. The second light shielding unit 1315 includes a third light shielding block extending along the row direction, the orthographic projection of the third light shielding block on the driving circuit layer 12 covers the channel region of the active portion T4C of the writing transistor T4.

The first light shielding structure 131 may further include the second light shielding portion 1312, the second light shielding portion 1312 includes a plurality of interconnected third light shielding units 1317. The third light shielding units 1317 are light shielding line segments that extend along the row direction and have approximately equal dimensions along the column direction. The orthographic projection of one light shielding line segment on the driving circuit layer 12 covers the active portion T1C of the first reset transistor T1 and the active portion T7C of the second reset transistor T7 of the pixel circuit in the previous row.

The second light shielding structure 132 may include a plurality of fourth light shielding units 1321 connected by the second connection line 1322, and the orthographic projection of the fourth light shielding unit 1321 on the driving circuit layer 12 covers the active portion T3C of the driving transistor T3.

The first and second light shielding portions 1311 and 1312 of the plurality of first light shielding structures 131 are arranged in a staggered manner along the column direction, and the second light shielding structure 132 is provided between the first and second light shielding portions 1311 and 1312 of the same first light shielding structure 131. The first and second light shielding portions 1311 and 1312 of the same first light shielding structure 131 are connected by three first traces 1313 extending along the column direction. It should be noted that two of the first traces 1313 are on the left and right sides of the light shielding layer 13 along the row direction, while the other first trace 1313 is between the first two traces 1313. A first pin 1318 connected to the first signal may be set on the first trace 1313 on the left side of the light shielding layer 13 and the first trace 1313 on the right side of the light shielding layer 13.

The second light shielding structure 132 at the bottom edge of the light shielding layer 13 along the column direction is continuous and uninterrupted. The remaining second light shielding structures 132 are divided into one second light shielding sub-structure 1320 between every two first traces 1313, and three first traces 1313 divide the second light shielding structure 132 into two second light shielding sub-structures 1320. The first light shielding portion 1311 at the top edge of the light shielding layer 13 along the column direction is continuous and uninterrupted. The remaining first light shielding portions 1311 and all second light shielding portions 1312 have two interruptions along the row direction, which divide the first light shielding portion 1311 into three first light shielding sub-portions 1310 and divide the second light shielding portion 1312 into three second light shielding sub-portions 1319. A interruption may be set between every two adjacent first traces 1313, located at the position where the first connecting line 1316 is set.

Two adjacent second light shielding sub-structures 1320 along the column direction are connected by the second trace 133 to form a first light shielding section 135. The second trace 133 is within the interruption, and the second trace 133 is usually connected to the fourth light shielding unit 1321 of two adjacent second light shielding sub-structures 1320. A second pin 1323 for inputting the second signal may be provided on the fourth light shielding unit 1321 on one side of the second trace 133 in the row direction of the second light shielding sub-structure 1320, or a second pin 1323 for inputting the second signal may be provided on the fourth light shielding unit 1321 on both sides of the second trace 133 in the row direction of the second light shielding sub-structure 1320.

The first light shielding portion 1311 and the second light shielding portion 1312 of different first light shielding structures 131 are connected by the third trace 134 extending along the column direction, and the third trace 134 is between the first trace 1313 and the second trace 133. In the present embodiment, the third trace 134 is provided at one end of the first light shielding sub-portion 1310 and the second light shielding sub-portion 1319 near the second trace 133, and the two third traces 134 are symmetrically arranged on both sides of the second trace 133. Specifically, one of the third traces 134 may be connected to the first light shielding unit 1314 of one first light shielding sub-portion 1310, and the other third trace 134 may be connected to the second light shielding unit 1315 of another first light shielding sub-portion 1310.

The first light shielding sub-portion 1310 and the second light shielding sub-portion 1319 at both ends of the first light shielding portion 1311 on the top edge are connected to the first trace 1313 at one end far away from the interruption, and to the third trace 134 at one end near the interruption. Therefore, the first light shielding structure 131 forms a continuous second light shielding section 136 at both ends of the first light shielding portion 1311 on the top edge, and the two ends of the first light shielding portion 1311 in the middle are respectively connected to the third trace 134. A plurality of rectangular light shielding rings are formed in the middle of the first light shielding portion 1311 on the top edge, and are connected to each other through the first trace 1313 to form a third light shielding section 137.

As shown in FIG. 5, the first light shielding portion 1311 and the second light shielding portion 1312 of the same first light shielding structure 131 are connected by the first trace 1313 extending along the column direction. The second light shielding structure 132 is between the first light shielding portion 1311 and the second light shielding portion 1312 of the same first light shielding structure 131, the second light shielding structure 132 is connected by the second trace 133 extending along the column direction. The first trace 1313 is on one side of the light shielding layer 13 along the row direction, and the second trace 133 is on the other side of the light shielding layer 13 along the row direction. It may be understood that the first trace 1313 and the second trace 133 are at both ends of the first light shielding structure 131 or the second light shielding structure 132 along the row direction.

It should be noted that the setting methods of the first pin 1318 and the second pin 1323 in FIG. 5 and FIG. 4 remain unchanged. The first pin 1318 for inputting the first signal is set on the first trace 1313, and the second pin 1323 for inputting the second signal is set on the second light shielding structure 132. The first light shielding portion 1311 and the second light shielding portion 1312 of different first light shielding structures 131 are connected by the third trace 134 extending along the column direction. In the present embodiment, the third trace 134 and the second trace 133 are located on the same straight line. In other feasible embodiments, the third trace 134 may also be provided at one end of the first light shielding portion 1311 and the second light shielding portion 1312 away from the first trace 1313 in the row direction, that is, a plurality of first light shielding portions 1311 and second light shielding portions 1312 are connected end-to-end.

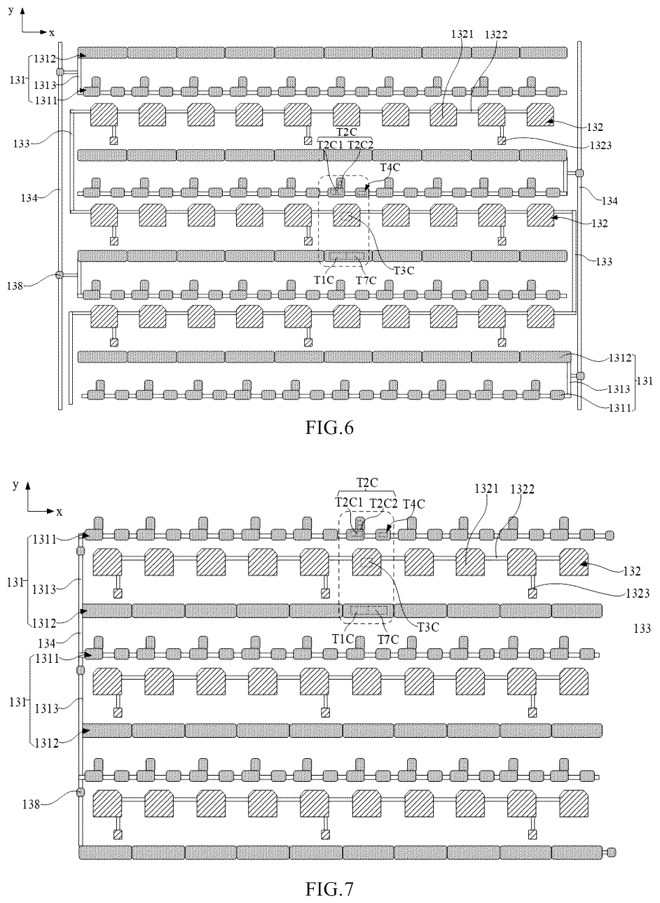

As shown in FIG. 6, the first light shielding portion 1311 and the second light shielding portion 1312 of the same first light shielding structure 131 are connected by the first trace 1313 extending along the column direction. The first traces 1313 of adjacent first light shielding structures 131 are on different sides of the light shielding layer 13 along the row direction. The second light shielding structure 132 is provided between the first light shielding portion 1311 and the second light shielding portion 1312 of adjacent first light shielding structures 131. Different second light shielding structures 132 are connected end-to-end by the second trace 133. The outer sides of the two first traces 1313 are respectively provided with a third trace 134, and the third trace 134 is connected to adjacent first traces 1313. The first pin 1318 may be provided on the third trace 134.

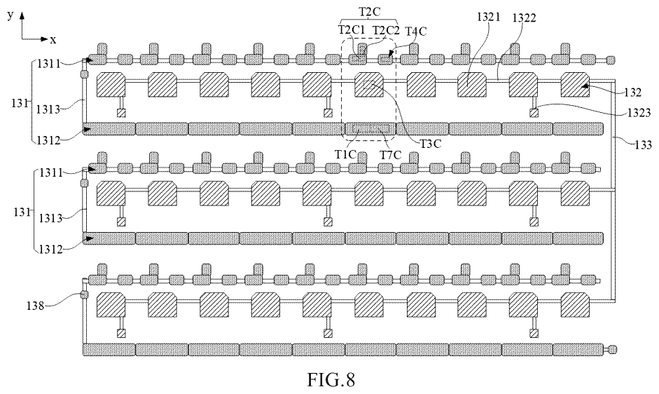

In other embodiments, as shown in FIG. 7, two adjacent first light shielding structures 131 may be connected together, while two adjacent second light shielding structures 132 are still set to be independent of each other. To a certain extent, it may also increase the static discharge area and path of the light shielding layer 13, so that the accumulated static electricity during the process may be timely released or evenly distributed. Alternatively, as shown in FIG. 8, adjacent second light shielding structures 132 may be connected together, while adjacent first light shielding structures 131 are still set to be independent of each other.

It should be noted that the row direction in FIG. 1 and FIGS. 4 to 8 is x direction, and the column direction is y direction.

Embodiments of the present disclosure further provide a display device. The display device may include the display panel according to any one of the embodiments of the present disclosure. The specific structure and beneficial effects of the display panel have been explained in detail above, so they will not be repeated herein.

It should be noted that in addition to the display panel, the display device further includes other necessary components and compositions, such as circuit boards, power lines, etc. Those skilled in the art may supplement them according to the specific usage requirements of the display device, and will not repeat them herein.

When the display panel adopts the structure shown in the figures, the display device may be traditional electronic devices such as mobile phones, computers, televisions, and camcorders, or emerging wearable devices such as virtual reality devices and augmented reality devices, which will not be listed one by one herein.

After considering the specification and practicing the invention disclosed herein, those skilled in the art will easily come up with other implementation solutions disclosed herein. The present application aims to cover any variations, applications, or adaptive changes of the present disclosure, which follow the general principles of the present disclosure and include common knowledge or customary technical means in the art not disclosed in the present disclosure. The specification and embodiments are only considered exemplary, and the true scope and spirit of the present disclosure are indicated by the appended claims.

1. A display panel, comprising:
a base substrate;
a driving circuit layer provided on a side of the base substrate, the driving circuit layer comprising at least two pixel circuits arranged along a row direction and arranged along a column direction, the column direction being perpendicular to the row direction, and each pixel circuit comprising at least two types of transistors for receiving different signals; and
a light shielding layer provided between the driving circuit layer and the base substrate, the light shielding layer comprising at least two light shielding structure groups, each light shielding structure group comprising a first light shielding structure and a second light shielding structure, the first light shielding structure inputting a first signal, the second light shielding structure inputting a second signal, the first light shielding structure and the second light shielding structure extending along the row direction, and at least two first light shielding structures and at least two second light shielding structures arranged along the column direction,
wherein one of the light shielding structure groups blocks one of the pixel circuits: an orthographic projection of the first light shielding structure on the driving circuit layer and an orthographic projection of the second light shielding structure on the driving circuit layer separately overlap with active portions of different types of transistors; and two adjacent first light shielding structures are connected together and/or two adjacent second light shielding structures are connected together.

2. The display panel according to claim 1, wherein each pixel circuit comprises a first reset transistor, a compensation transistor, a driving transistor, a writing transistor, a first light-emitting control transistor, a second light-emitting control transistor, a second reset transistor, and a storage capacitor;
a first pole of the first reset transistor is configured to receive a first reset signal, and a second pole of the first reset transistor is connected to a gate of the driving transistor and a first pole plate of the storage capacitor;
a first pole of the compensation transistor is connected to a second pole of the driving transistor, and a second pole of the compensation transistor is connected to the gate of the driving transistor; the compensation transistor has two channels connected in series;
a first pole of the writing transistor is connected to a data line, and a second pole of the writing transistor is connected to a first pole of the driving transistor;
a first pole of the first light-emitting control transistor and a second pole plate of the storage capacitor are connected by a power line, and a second pole of the first light-emitting control transistor is connected to the first pole of the driving transistor;
a first pole of the second light-emitting control transistor is connected to the second pole of the driving transistor, and a second pole of the second light-emitting control transistor is connected to a first electrode of a light-emitting device;
a first pole of the second reset transistor is configured to receive a second reset signal, and a second pole of the second reset transistor is connected to the second pole of the second light-emitting control transistor;
the orthographic projection of the first light shielding structure on the driving circuit layer overlaps with an active portion of the first reset transistor, an active portion of a threshold compensation transistor, an active portion of the writing transistor, and an active portion of the second reset transistor of the pixel circuit in a previous row; the orthographic projection of the second light shielding structure on the driving circuit layer overlaps with an active portion of the driving transistor.

3. The display panel according to claim 2, wherein the first light shielding structure comprises a first light shielding portion and a second light shielding portion; the first light shielding portion and the second light shielding portion extend along the row direction and are arranged along the column direction; an orthographic projection of the first light shielding portion on the driving circuit layer overlaps with an active portion of the compensation transistor and the active portion of the writing transistor; and an orthographic projection of the second light shielding portion on the driving circuit layer overlaps with the active portion of the first reset transistor and the active portion of the second reset transistor of the pixel circuit in the previous row.

4. The display panel according to claim 3, wherein first light shielding portions and second light shielding portions of at least two first light shielding structures are arranged alternately along the column direction, and the second light shielding structure is provided between the first light shielding portion and the second light shielding portion of a same first light shielding structure, or between the first light shielding portion and the second light shielding portion of adjacent first light shielding structures.

5. The display panel according to claim 4, wherein two adjacent first light shielding structures are connected together, and two adjacent second light shielding structures are connected together.

6. The display panel according to claim 5, wherein the first light shielding portion and the second light shielding portion of the same first light shielding structure are connected by at least three first traces extending along the column direction, the first light shielding portion on one side of the light shielding layer along the column direction is continuous and uninterrupted, the remaining first light shielding portion and all the second light shielding portions are provided with at least two interruptions along the row direction, and there is one interruption between every two adjacent first traces;
the second light shielding structure is provided between the first light shielding portion and the second light shielding portion of the same first light shielding structure, the second light shielding structure on another side of the light shielding layer along the column direction is continuous and uninterrupted, the remaining second light shielding structure is partitioned into a second light shielding sub-structure between every two of the first traces, two adjacent second light shielding sub-structures along the column direction are connected by a second trace, and the second trace is within the interruption;
the first light shielding portion and the second light shielding portion of different first light shielding structures are connected by a third trace extending along the column direction, the third trace is between the first trace and the second trace.

7. The display panel according to claim 5, wherein the first light shielding portion and the second light shielding portion of the same first light shielding structure are connected by a first trace extending along the column direction; the second light shielding structure is provided between the first light shielding portion and the second light shielding portion of the same first light shielding structure; the second light shielding structure is connected by a second trace extending along the column direction; the first trace is on one side of the light shielding layer along the row direction; the second trace is on another side of the light shielding layer along the row direction; the first light shielding portion and the second light shielding portion of different first light shielding structures are connected by a third trace extending along the column direction.

8. The display panel according to claim 7, wherein the third trace and the second trace are on a same straight line.

9. The display panel according to claim 5, wherein one end of the first light shielding portion and one end of the second light shielding portion of the same first light shielding structure are connected by a first trace extending along the column direction; the second light shielding structure is provided between the first light shielding portion and the second light shielding portion of adjacent first light shielding structures: different second light shielding structures are connected end-to-end by a second trace, and the second trace is provided along the row direction at one end of the first light shielding structure away from the first trace; first traces of adjacent first light shielding structures are respectively on different sides of the light shielding layer along the row direction; and one third trace is provided on an outer side of each of the two first traces, and the third trace is connected to the first trace adjacent thereto.

10. The display panel according to claim 6, wherein the first light shielding portion comprises a plurality of first light shielding units and a plurality of second light shielding units connected by a first connection line; the first light shielding units and the second light shielding units are alternately arranged along the row direction; at least one first light shielding unit and at least one second light shielding unit are provided between every two adjacent second traces; an orthographic projection of each first light shielding unit on the driving circuit layer overlaps with the active portion of the compensation transistor; and an orthographic projection of the second light shielding unit on the driving circuit layer overlaps with the active portion of the writing transistor.

11. The display panel according to claim 10, wherein the active portion of the compensation transistor comprises a first channel region and a second channel region, the first light shielding unit comprises a first light shielding block and a second light shielding block connected to each other, the first light shielding block extends along the row direction, the second light shielding block extends along the column direction, an orthographic projection of the first light shielding block on the driving circuit layer overlaps with the first channel region, and an orthographic projection of the second light shielding block on the driving circuit layer overlaps with the second channel region.

12. The display panel according to claim 5. wherein the second light shielding portion comprises a plurality of third light shielding units connected to each other. and an orthographic projection of each third light shielding unit on the driving circuit layer overlaps with the active portion of the first reset transistor and the active portion of the second reset transistor of the pixel circuit in the previous row.

13. A display device comprising a display panel, wherein the display panel comprises:
a base substrate;
a driving circuit layer provided on a side of the base substrate, the driving circuit layer comprising at least two pixel circuits arranged along a row direction and arranged along a column direction, the column direction being perpendicular to the row direction, and each pixel circuit comprising at least two types of transistors for receiving different signals; and
a light shielding layer provided between the driving circuit layer and the base substrate. the light shielding layer comprising at least two light shielding structure groups, each light shielding structure group comprising a first light shielding structure and a second light shielding structure, the first light shielding structure inputting a first signal, the second light shielding structure inputting a second signal, the first light shielding structure and the second light shielding structure extending along the row direction, and at least two first light shielding structures and at least two second light shielding structures arranged along the column direction,
wherein one of the light shielding structure groups blocks one of the pixel circuits; an orthographic projection of the first light shielding structure on the driving circuit layer and an orthographic projection of the second light shielding structure on the driving circuit layer separately overlap with active portions of different types of transistors; and two adjacent first light shielding structures are connected together and/or two adjacent second light shielding structures are connected together.

14. The display panel according to claim 7, wherein the first light shielding portion comprises a plurality of first light shielding units and a plurality of second light shielding units connected by a first connection line; the first light shielding units and the second light shielding units are alternately arranged along the row direction; at least one first light shielding unit and at least one second light shielding unit are provided between every two adjacent second traces; an orthographic projection of each first light shielding unit on the driving circuit layer overlaps with the active portion of the compensation transistor; and an orthographic projection of the second light shielding unit on the driving circuit layer overlaps with the active portion of the writing transistor.

15. The display panel according to claim 9, wherein the first light shielding portion comprises a plurality of first light shielding units and a plurality of second light shielding units connected by a first connection line; the first light shielding units and the second light shielding units are alternately arranged along the row direction; at least one first light shielding unit and at least one second light shielding unit are provided between every two adjacent second traces: an orthographic projection of each first light shielding unit on the driving circuit layer overlaps with the active portion of the compensation transistor; and an orthographic projection of the second light shielding unit on the driving circuit layer overlaps with the active portion of the writing transistor.

16. The display panel according to claim 14, wherein the active portion of the compensation transistor comprises a first channel region and a second channel region, the first light shielding unit comprises a first light shielding block and a second light shielding block connected to each other, the first light shielding block extends along the row direction, the second light shielding block extends along the column direction, an orthographic projection of the first light shielding block on the driving circuit layer overlaps with the first channel region, and an orthographic projection of the second light shielding block on the driving circuit layer overlaps with the second channel region.

17. The display panel according to claim 15, wherein the active portion of the compensation transistor comprises a first channel region and a second channel region, the first light shielding unit comprises a first light shielding block and a second light shielding block connected to each other, the first light shielding block extends along the row direction, the second light shielding block extends along the column direction, an orthographic projection of the first light shielding block on the driving circuit layer overlaps with the first channel region, and an orthographic projection of the second light shielding block on the driving circuit layer overlaps with the second channel region.

18. The display device according to claim 17, wherein each pixel circuit comprises a first reset transistor, a compensation transistor, a driving transistor, a writing transistor, a first light-emitting control transistor, a second light-emitting control transistor, a second reset transistor, and a storage capacitor;
a first pole of the first reset transistor is configured to receive a first reset signal, and a second pole of the first reset transistor is connected to a gate of the driving transistor and a first pole plate of the storage capacitor;
a first pole of the compensation transistor is connected to a second pole of the driving transistor, and a second pole of the compensation transistor is connected to the gate of the driving transistor; the compensation transistor has two channels connected in series;
a first pole of the writing transistor is connected to a data line, and a second pole of the writing transistor is connected to a first pole of the driving transistor;
a first pole of the first light-emitting control transistor and a second pole plate of the storage capacitor are connected by a power line, and a second pole of the first light-emitting control transistor is connected to the first pole of the driving transistor;
a first pole of the second light-emitting control transistor is connected to the second pole of the driving transistor, and a second pole of the second light-emitting control transistor is connected to a first electrode of a light-emitting device;
a first pole of the second reset transistor is configured to receive a second reset signal, and a second pole of the second reset transistor is connected to the second pole of the second light-emitting control transistor;
the orthographic projection of the first light shielding structure on the driving circuit layer overlaps with an active portion of the first reset transistor, an active portion of a threshold compensation transistor, an active portion of the writing transistor, and an active portion of the second reset transistor of the pixel circuit in a previous row; the orthographic projection of the second light shielding structure on the driving circuit layer overlaps with an active portion of the driving transistor.

19. The display device according to claim 18, wherein the first light shielding structure comprises a first light shielding portion and a second light shielding portion; the first light shielding portion and the second light shielding portion extend along the row direction and are arranged along the column direction; an orthographic projection of the first light shielding portion on the driving circuit layer overlaps with an active portion of the compensation transistor and the active portion of the writing transistor; and an orthographic projection of the second light shielding portion on the driving circuit layer overlaps with the active portion of the first reset transistor and the active portion of the second reset transistor of the pixel circuit in the previous row.

20. The display device according to claim 19, wherein first light shielding portions and second light shielding portions of at least two first light shielding structures are arranged alternately along the column direction, and the second light shielding structure is provided between the first light shielding portion and the second light shielding portion of a same first light shielding structure, or between the first light shielding portion and the second light shielding portion of adjacent first light shielding structures.
